(19) United States
(12) Patent Application Publication
(10) Pub. No.: US 2023/0397397 A1
(43) Pub. Date: Dec. 7, 2023

(54) SEMICONDUCTOR ELEMENT MEMORY DEVICE

(71) Applicant: Unisantis Electronics Singapore Pte., Ltd., Singapore (SG)

(72) Inventors: Koji SAKUI, Tokyo (JP); Nozomu HARADA, Tokyo (JP)

(21) Appl. No.: 18/450,767

(22) Filed: Aug. 16, 2023

Related U.S. Application Data
(63) Continuation-in-part of application No. PCT/JP2021/006546, filed on Feb. 22, 2021.

(51) Int. Cl. H10B 12/00; G11C 11/404; G11C 11/4096

(52) U.S. Cl. CPC H10B 12/20; G11C 11/4096; G11C 11/404

(57) ABSTRACT

A memory device according to the present invention includes memory cells each of which is formed of a semiconductor body that stands on a substrate in a vertical direction relative to the substrate, voltages applied to a first gate conductor layer, a second gate conductor layer, a first impurity region, and a second impurity region of the memory cell are controlled to perform a write operation of retaining a group of positive holes, generated by an impact ionization phenomenon or a gate-induced drain leakage current, inside a semiconductor body, and the voltages applied to the first gate conductor layer, the second gate conductor layer, the first impurity region, and the second impurity region are controlled to perform an erase operation of discharging the group of positive holes from inside the semiconductor body. The first impurity region of the memory cell is connected to a source line wiring layer, the second impurity region thereof is connected to a bit line wiring layer, one of the first gate conductor layer or the second gate conductor layer thereof is connected to a word line wiring layer, and the other of the first gate conductor layer or the second gate conductor layer is connected to a first driving control line wiring layer, and in the vertical direction relative to the substrate, the source line wiring layer is connected to the first impurity region at a position lower than the first driving control line wiring layer and the word line wiring layer.

### CROSS REFERENCES TO RELATED APPLICATIONS

The present application is a Continuation-In-Part application of PCT/JP2021/006546, filed Feb. 22, 2021, the entire contents of which are incorporated herein by reference.

### BACKGROUND OF THE INVENTION

### 1. Field of the Invention

The present invention relates to a semiconductor-element-including semiconductor memory device.

### 2. Description of the Related Art

Recently, there has been a demand for highly integrated and high-performance memory elements in the development of LSI (Large Scale Integration) technology.

Typical planar MOS transistors include a channel that extends in a horizontal direction along the upper surface of the semiconductor substrate. In contrast, SGTs include a channel that extends in a direction perpendicular to the upper surface of the semiconductor substrate (see, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Accordingly, the density of semiconductor devices can be made higher with SGTs than with planar MOS transistors. Such SGTs can be used as selection transistors to implement highly integrated memories, such as a DRAM (Dynamic Random Access Memory, see, for example, H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) to which a capacitor is connected, a PCM (Phase Change Memory, see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)) to which a resistance change element is connected, an RRAM (Resistive Random Access Memory, see, for example, T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3V”, IEDM (2007)), and an MRAM (Magneto-resistive Random Access Memory, see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) that changes the resistance by changing the orientation of a magnetic spin with a current. Further, there exists, for example, a DRAM memory cell (see M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)) constituted by a single MOS transistor and including no capacitor. The present application relates to a dynamic flash memory that can be constituted only by a MOS transistor and that includes no resistance change element or capacitor.

FIGS. 7A, 7B, 7C and 7D illustrate a write operation of a DRAM memory cell constituted by a single MOS transistor and including no capacitor described above, FIGS. 8A and 8B illustrate a problem in the operation, and FIGS. 9A, 9B and 9C illustrate a read operation (see J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), and E. Yoshida and T. Tanaka: “A design of a capacitorless 1T-DRAM cell using gate-induced drain leakage (GIDL) current for low-power and high-speed embedded memory”, IEEE IEDM, pp. 913-916, December 2003). FIG. 7A illustrates a “1” write state. Here, the memory cell is formed on an SOI substrate 100, is constituted by a source N⁺ layer 103 (hereinafter, a semiconductor region that contains a donor impurity in high concentrations is referred to as “N⁺ layer”) to which a source line SL is connected, a drain N⁺ layer 104 to which a bit line BL is connected, a gate conductor layer 105 to which a word line WL is connected, and a floating body 102 of a MOS transistor 110, and includes no capacitor. The single MOS transistor 110 constitutes the DRAM memory cell. Directly under the floating body 102, a SiO₂ layer 101 of the SOI substrate is in contact with the floating body 102. To write “1” to the memory cell constituted by the single MOS transistor 110, the MOS transistor 110 is operated in the saturation region. That is, a channel 107, for electrons, extending from the source N⁺ layer 103 has a pinch-off point 108 and does not reach the drain N⁺ layer 104 to which the bit line is connected. When a high voltage is applied to both of the bit line BL connected to the drain N⁺ layer and the word line WL connected to the gate conductor layer 105, and the MOS transistor 110 is operated at the gate voltage that is about one-half of the drain voltage, the electric field intensity becomes maximum at the pinch-off point 108 that is in the vicinity of the drain N⁺ layer 104. As a result, accelerated electrons that flow from the source N+layer 103 toward the drain N⁺ layer 104 collide with the Si lattice, and with kinetic energy lost at the time of collision, electron-positive hole pairs are generated (impact ionization phenomenon). Most of the generated electrons (not illustrated) reach the drain N⁺ layer 104. Further, a very small proportion of the electrons that are very hot pass through a gate oxide film 109 and reach the gate conductor layer 105. With positive holes 106 that are simultaneously generated, the floating body 102 is charged. In this case, the generated positive holes contribute to an increase in the majority carriers because the floating body 102 is P-type Si. When the floating body 102 is filled with the generated positive holes 106 and the voltage of the floating body 102 becomes higher than that of the source N⁺ layer 103 by Vb or more, further generated positive holes are discharged to the source N⁺ layer 103. Here, Vb is the built-in voltage of the PN junction between the source N⁺ layer 103 and the P-layer floating body 102 and is equal to about 0.7 V. FIG. 7B illustrates a state in which the floating body 102 is charged to saturation with the generated positive holes 106.

Now, a “0” write operation of the memory cell 110 will be described with reference to FIG. 7C. For the common selected word line WL, the memory cell 110 to which “1” is written and the memory cell 110 to which “0” is written are present at random. FIG. 7C illustrates a state of rewriting from a “1” write state to a “0” write state. To write “0”, the voltage of the bit line BL is set to a negative bias, and the PN junction between the drain N⁺ 104 and the P-layer floating body 102 is forward biased. As a result, the positive holes 106 in the floating body 102 generated in advance in the previous cycle flow into the drain N⁺ layer 104 that is connected to the bit line BL. When the write operation ends, the two memory cells are in a state in which the memory cell 110 (FIG. 7B) is filled with the generated positive holes 106, and from the memory cell 110 (FIG. 7C), the generated positive holes are discharged. The potential of the floating body 102 of the memory cell 110 filled with the positive holes 106 becomes higher than that of the floating body 102 in which generated positive holes are not present. Therefore, the threshold voltage of the memory cell 110 to which “1” is written becomes lower than the threshold voltage of the memory cell 110 to which “0” is written. This is illustrated in FIG. 7D.

Now, a problem in the operation of the memory cell constituted by the single MOS transistor 110 will be described with reference to FIGS. 8A and 8B. As illustrated in FIG. 8A, the capacitance C_{FB} of the floating body is equal to the sum of the capacitance C_{WL} between the gate to which the word line is connected and the floating body, the junction capacitance C_{SL} of the PN junction between the source N⁺ layer 103 to which the source line is connected and the floating body 102, and the junction capacitance CBL of the PN junction between the drain N⁺ layer 104 to which the bit line is connected and the floating body 102 and is expressed as follows.

C_{FB}=C_{WL}+C_{BL}+C_{SL} (10)

The capacitive coupling ratio 3_{WL} between the gate to which the word line is connected and the floating body is expressed as follows.

↑_{WL}=C_{WL}C_{WL}+C_{SL} (11)

Therefore, a change in the word line voltage V_{WL} at the time of reading or writing affects the voltage of the floating body 102 that functions as a storage node (contact point) of the memory cell. This is illustrated in FIG. 8B. When the word line voltage V_{WL} rises from 0 V to V_{WLH} at the time of reading or writing, the voltage V_{FB} of the floating body 102 rises from V_{FB1}, which is the voltage in the initial state before the word line voltage changes, to V_{FB2} due to capacitive coupling with the word line. The voltage change amount ΔV_{FB} is expressed as follows.

ΔV_{FB}=V_{FB2}−V_{FB1}=β_{WL}×V_{WLN} (12)

Here, for β_{WL} in expression (11), the contribution ratio of C_{WL} is large and, for example, C_{WL}:C_{BL}:C_{SL}=8:1:1 holds. This results in β_{WL}=0.8. When the word line changes, for example, from 5 V at the time of writing to 0 V after the end of writing, the floating body 102 receives an amplitude noise of 5 V×β_{WL}=4 V due to capacitive coupling between the word line WL and the floating body 102. Accordingly, a sufficient margin is not provided to the potential difference between the “1” potential and the “0” potential of the floating body 102 at the time of writing, which has been a problem.

FIGS. 9A, 9B and 9C illustrate a read operation where FIG. 9A illustrates a “1” write state and FIG. 9B illustrates a “0” write state. In actuality, however, even when Vb is set for the floating body 102 to write “1”, once the word line returns to 0 V at the end of writing, the floating body 102 is lowered to a negative bias. When “0” is written, the floating body 102 is lowered to a further negative bias, and it is difficult to provide a sufficiently large margin to the potential difference between “1” and “0” at the time of writing as illustrated in FIG. 9C. Therefore, there has been difficulty in commercially introducing DRAM memory cells actually including no capacitor.

### SUMMARY OF THE INVENTION

In capacitor-less single-transistor DRAMs (gain cells), capacitive coupling between the word line and the floating body is strong. When the potential of the word line is changed at the time of data reading or at the time of data writing, the change is directly transmitted to the floating body as noise, which has been a problem. This causes a problem of erroneous reading or erroneous rewriting of storage data, and it has been difficult to commercially introduce capacitor-less single-transistor DRAMs (gain cells).

To address the above-described problems, a semiconductor element memory device according to the present invention is a semiconductor element memory device including a plurality of memory cells disposed in a matrix, each of the memory cells including:

a semiconductor body that stands on a substrate in a vertical direction relative to the substrate;

a first impurity region and a second impurity region that are respectively disposed at a lower end and an upper end of the semiconductor body in the vertical direction relative to the substrate;

a gate insulator layer that is in contact with a side surface of the semiconductor body between the first impurity region and the second impurity region;

a first gate conductor layer that partially or entirely covers the gate insulator layer; and

a second gate conductor layer that is adjacent to the first gate conductor layer and that is in contact with a side surface of the gate insulator layer, in which

in each of the memory cells,

voltages applied to the first gate conductor layer, the second gate conductor layer, the first impurity region, and the second impurity region are controlled to retain a group of positive holes, generated by an impact ionization phenomenon or a gate-induced drain leakage current, inside the semiconductor body,

in a write operation, a voltage of the semiconductor body is made equal to a first data retention voltage that is higher than the voltage of one of the first impurity region or the second impurity region or the voltages of both of the first impurity region and the second impurity region,

in an erase operation, the voltages applied to the first impurity region, the second impurity region, the first gate conductor layer, and the second gate conductor layer are controlled to discharge the group of positive holes through one or both of the first impurity region and the second impurity region, and the voltage of the semiconductor body is made equal to a second data retention voltage lower than the first data retention voltage,

the first impurity region of the memory cell is connected to a source line wiring layer, the second impurity region thereof is connected to a bit line wiring layer, one of the first gate conductor layer or the second gate conductor layer thereof is connected to a word line wiring layer, and the other of the first gate conductor layer or the second gate conductor layer is connected to a first driving control line wiring layer, and

in the vertical direction relative to the substrate, the source line wiring layer is connected to the first impurity region at a position lower than the first driving control line wiring layer and the word line wiring layer (first invention).

In the first invention described above, in the vertical direction relative to the substrate, the source line wiring layer is disposed in a layer lower than the first driving control line wiring layer and the word line wiring layer (second invention).

In the first invention described above, the source line wiring layer is disposed parallel to the bit line wiring layer (third invention).

In the first invention described above, the source line wiring layer is disposed perpendicular to the word line wiring layer (fourth invention).

In the first invention described above, the source line wiring layer is disposed perpendicular to the bit line wiring layer (fifth invention).

In the first invention described above, the source line wiring layer is disposed parallel to the word line wiring layer (sixth invention).

In the third invention described above, one source line wiring layer is disposed for each of pluralities of bit line wiring layers each of which is the bit line wiring layer (seventh invention).

In the sixth invention described above, one source line wiring layer is disposed for each of pluralities of word line wiring layers each of which is the word line wiring layer (eighth invention).

In the seventh invention described above, one source line wiring layer is disposed for each of the pluralities of bit line wiring layers in binary multiples (ninth invention).

In the eighth invention described above, one source line wiring layer is disposed for each of the pluralities of word line wiring layers in binary multiples (tenth invention).

In the first invention described above, a first gate capacitance between the first gate conductor layer and the semiconductor body is larger than a second gate capacitance between the second gate conductor layer and the semiconductor body (eleventh invention).

In the first invention described above, one or both of the first gate conductor layer and the second gate conductor layer is divided into two or more isolated gate conductor layers in plan view or in the vertical direction, and the isolated gate conductor layers are operated synchronously or asynchronously (twelfth invention).

In the twelfth invention described above, in the vertical direction, the isolated gate conductor layers obtained from one of the first gate conductor layer or the second gate conductor layer are disposed on respective sides of the other of the first gate conductor layer or the second gate conductor layer (thirteenth invention).

### BRIEF DESCRIPTION OF THE DRAWINGS

FIG. 1 is a structural diagram of an SGT-including memory device according to a first embodiment;

FIGS. 2A, 2B and 2C are diagrams for explaining an effect attained in a case where the gate capacitance of a first gate conductor layer 5a connected to a plate line wiring layer PL is made larger than the gate capacitance of a second gate conductor layer 5b to which a word line wiring layer WL is connected in the SGT-including memory device according to the first embodiment;

FIGS. 3AA, 3AB and 3AC are diagrams for explaining a mechanism of a write operation of the SGT-including memory device according to the first embodiment;

FIG. 3B includes diagrams for explaining the mechanism of the write operation of the SGT-including memory device according to the first embodiment;

FIG. 4A is a diagram for explaining a mechanism of an erase operation of the SGT-including memory device according to the first embodiment;

FIGS. 4BA, 4BB, 4BC and 4BD are diagrams for explaining the mechanism of the erase operation of the SGT-including memory device according to the first embodiment;

FIG. 4C includes diagrams for explaining the mechanism of the erase operation of the SGT-including memory device according to the first embodiment;

FIGS. 4DA, 4DB, 4DC and 4DD are diagrams for explaining a mechanism of the erase operation of the SGT-including memory device according to the first embodiment;

FIGS. 5AA, 5AB and 5AC are diagrams for explaining a disposition structure of a source line wiring layer, a word line wiring layer, and a bit line wiring layer of the SGT-including memory device according to the first embodiment;

FIGS. 5BA, 5BB and 5BC are diagrams for explaining a disposition structure of the source line wiring layer, the word line wiring layer, and the bit line wiring layer of the SGT-including memory device according to the first embodiment;

FIGS. 6A, 6B and 6C are diagrams for explaining a mechanism of a read operation of the SGT-including memory device according to the first embodiment;

FIGS. 7A, 7B, 7C and 7D are diagrams for explaining a write operation of a DRAM memory cell including no capacitor in the related art;

FIGS. 8A and 8B are diagrams for explaining a problem in the operation of the DRAM memory cell including no capacitor in the related art; and

FIGS. 9A, 9B and 9C are diagrams for explaining a read operation of the DRAM memory cell including no capacitor in the related art.

### DESCRIPTION OF THE PREFERRED EMBODIMENTS

Hereinafter, a semiconductor-element-including memory device (hereinafter called a dynamic flash memory) according to the present invention will be described with reference to the drawings.

### First Embodiment

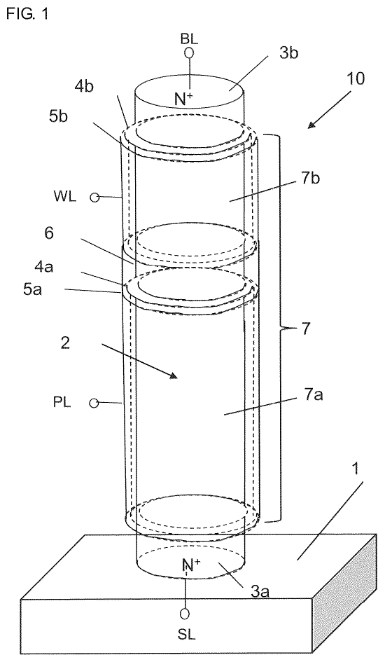

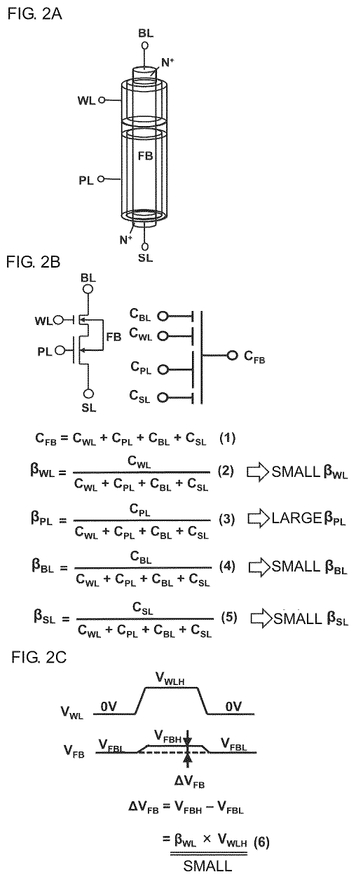

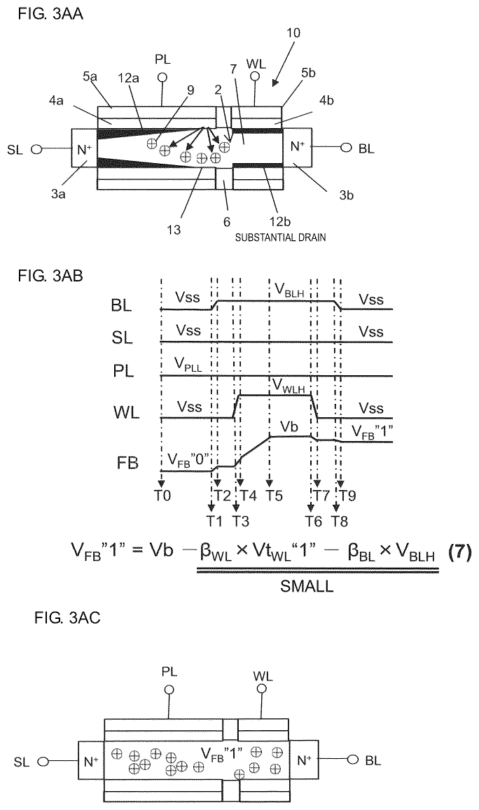

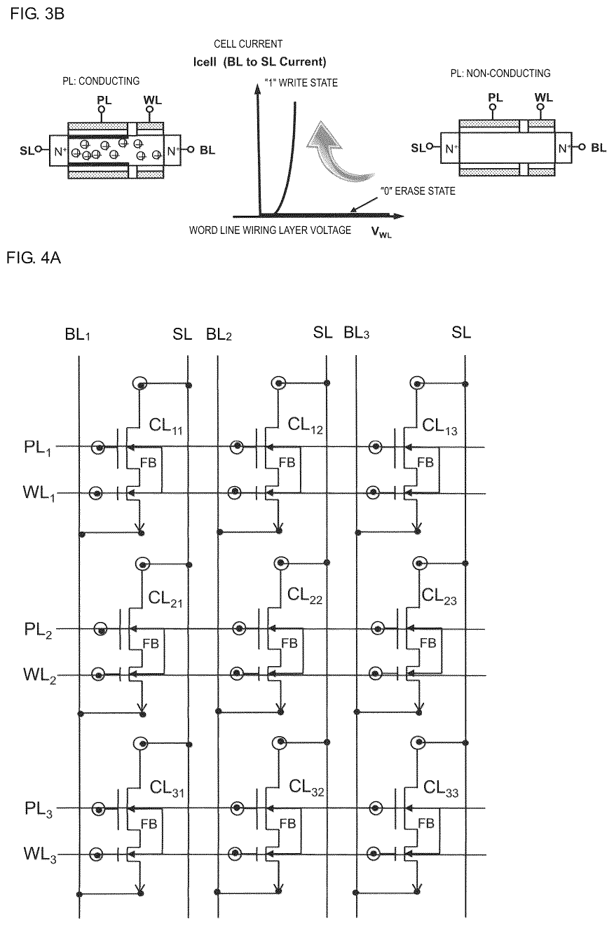

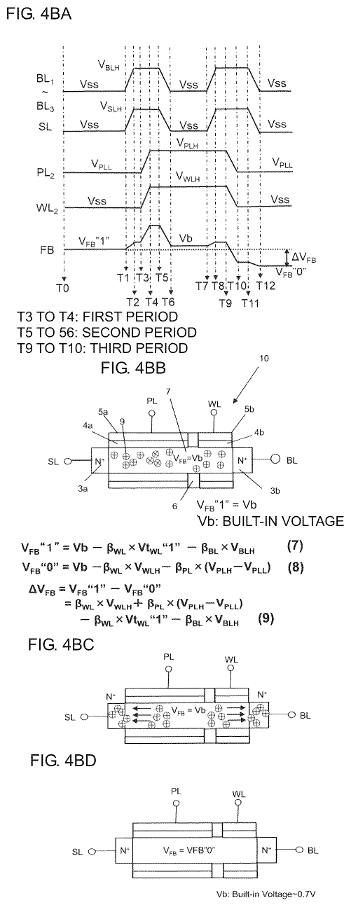

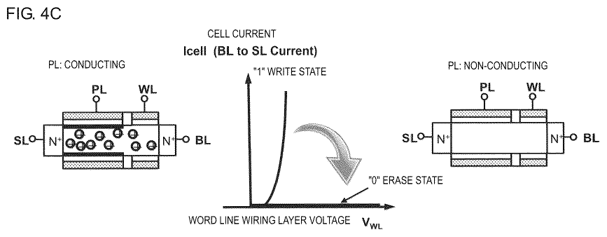

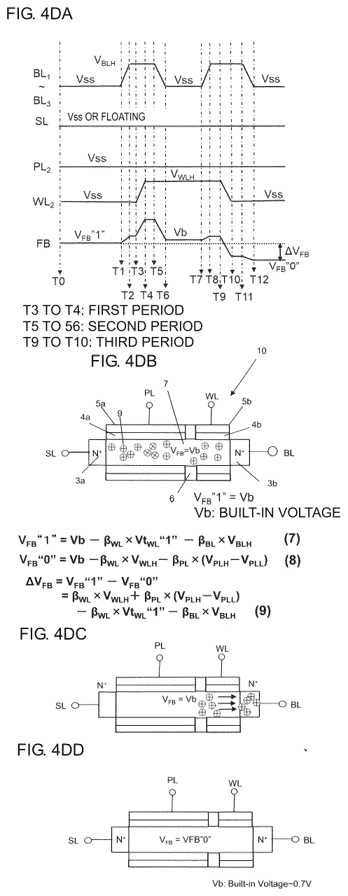

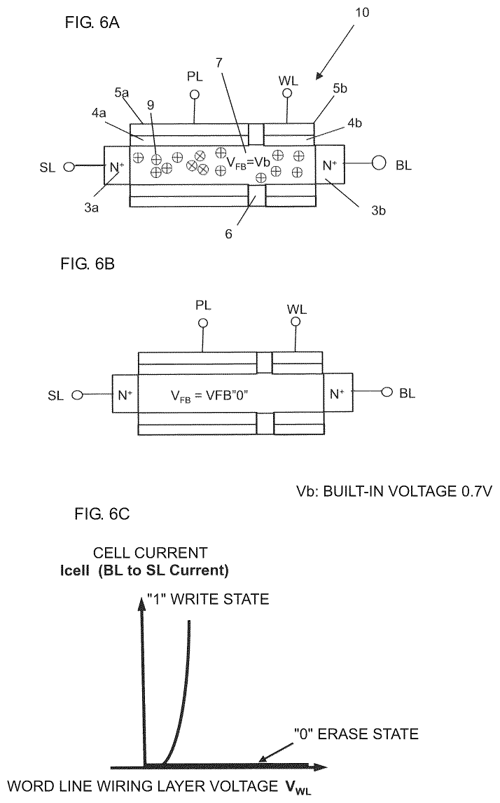

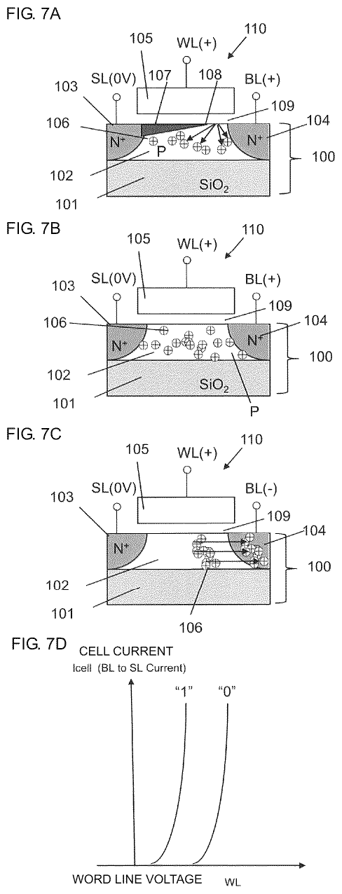

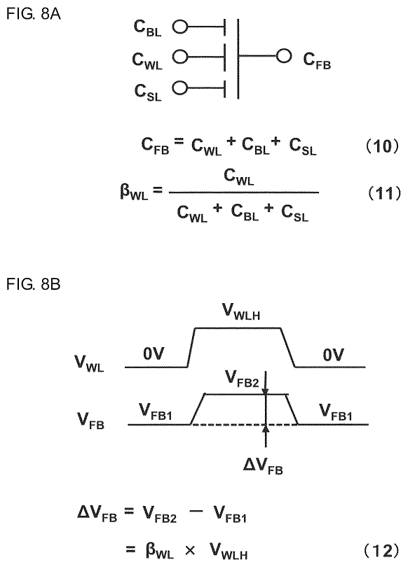

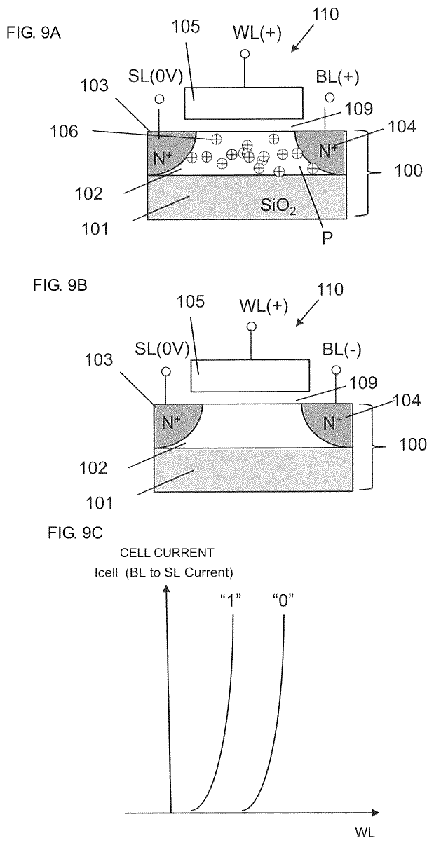

The structure and operation mechanisms of a dynamic flash memory cell according to a first embodiment of the present invention will be described with reference to FIG. 1 to FIGS. 6A, 6B and 6C. The structure of the dynamic flash memory cell will be described with reference to FIG. 1. An effect attained in a case where the gate capacitance of a first gate conductor layer 5a connected to a plate line wiring layer PL is made larger than the gate capacitance of a second gate conductor layer 5b to which a word line wiring layer WL is connected will be described with reference to FIGS. 2A, 2B and 2C. A mechanism of a data write operation will be described with reference to FIGS. 3AA, 3AB, 3AC and FIG. 3B, mechanisms of a data erase operation will be described with reference to FIG. 4A to FIGS. 4DA, 4DB, 4DC and 4DD, and a mechanism of a data read operation will be described with reference to FIGS. 6A, 6B and 6C.

FIG. 1 illustrates the structure of the dynamic flash memory cell according to the first embodiment of the present invention. At top and bottom positions in a silicon semiconductor column 2 (the silicon semiconductor column is hereinafter referred to as “Si column”) (which is an example of “semiconductor body” in the claims) of the P or i (intrinsic) conductivity type formed on a substrate 1 (which is an example of “substrate” in the claims), N⁺ layers 3a and 3b (which are examples of “first impurity region” and “second impurity region” in the claims), one of which functions as the source and the other functions as the drain, are formed. A part of the Si column 2 between the N⁺ layers 3a and 3b that function as the source and the drain functions as a semiconductor body 7 (which is an example of “semiconductor body” in the claims). Around the semiconductor body 7, a first gate insulator layer 4a (which is an example of “gate insulator layer” in the claims) and a second gate insulator layer 4b (which is an example of “gate insulator layer” in the claims) are formed. The first gate insulator layer 4a and the second gate insulator layer 4b are in contact with or in close vicinity to the N⁺ layers 3a and 3b that function as the source and the drain respectively. Around the first gate insulator layer 4a and the second gate insulator layer 4b, the first gate conductor layer 5a (which is an example of “first gate conductor layer” in the claims) and the second gate conductor layer 5b (which is an example of “second gate conductor layer” in the claims) are formed respectively. The first gate conductor layer 5a and the second gate conductor layer 5b are isolated from each other by an insulating layer 6. The semiconductor body 7 between the N⁺ layers 3a and 3b is constituted by a first channel Si layer 7a surrounded by the first gate insulator layer 4a and a second channel Si layer 7b surrounded by the second gate insulator layer 4b.

Accordingly, the N⁺ layers 3a and 3b that function as the source and the drain, the semiconductor body 7, the first gate insulator layer 4a, the second gate insulator layer 4b, the first gate conductor layer 5a, and the second gate conductor layer 5b constitute a dynamic flash memory cell 10. The N⁺ layer 3a that functions as the source is connected to a source line wiring layer SL (which is an example of “source line wiring layer” in the claims), the N+layer 3b that functions as the drain is connected to a bit line wiring layer BL (which is an example of “bit line wiring layer” in the claims), the first gate conductor layer 5a is connected to the plate line wiring layer PL (which is an example of “first driving control line wiring layer” in the claims), and the second gate conductor layer 5b is connected to the word line wiring layer WL (which is an example of “word line wiring layer” in the claims). Desirably, the dynamic flash memory cell has a structure in which the gate capacitance of the first gate conductor layer 5a to which the plate line wiring layer PL is connected is larger than the gate capacitance of the second gate conductor layer 5b to which the word line wiring layer WL is connected.

In FIG. 1, to make the gate capacitance of the first gate conductor layer 5a connected to the plate line wiring layer PL larger than the gate capacitance of the second gate conductor layer 5b to which the word line wiring layer WL is connected, the gate length of the first gate conductor layer 5a is made longer than the gate length of the second gate conductor layer 5b. Alternatively, instead of making the gate length of the first gate conductor layer 5a longer than the gate length of the second gate conductor layer 5b, the thicknesses of the respective gate insulator layers may be made different such that the thickness of the gate insulating film of the first gate insulator layer 4a is thinner than the thickness of the gate insulating film of the second gate insulator layer 4b. Alternatively, the dielectric constants of the materials of the respective gate insulator layers may be made different such that the dielectric constant of the gate insulating film of the first gate insulator layer 4a is higher than the dielectric constant of the gate insulating film of the second gate insulator layer 4b. The gate capacitance of the first gate conductor layer 5a connected to the plate line wiring layer PL may be made larger than the gate capacitance of the second gate conductor layer 5b to which the word line wiring layer WL is connected, by a combination of any of the lengths of the gate conductor layers 5a and 5b and the thicknesses and dielectric constants of the gate insulator layers 4a and 4b.

FIGS. 2A, 2B and 2C are diagrams for explaining an effect attained in a case where the gate capacitance of the first gate conductor layer 5a connected to the plate line wiring layer PL is made larger than the gate capacitance of the second gate conductor layer 5b to which the word line wiring layer WL is connected.

FIG. 2A is a simplified structural diagram of the dynamic flash memory cell according to the first embodiment of the present invention and illustrates only main parts. To the dynamic flash memory cell, the bit line wiring layer BL, the word line wiring layer WL, the plate line wiring layer PL, and the source line wiring layer SL are connected, and the potential state of the semiconductor body 7 is determined by the voltage states of the wiring layers.

FIG. 2B is a diagram for explaining the capacitance relationships of the respective wiring layers. The capacitance C_{FB} of the semiconductor body 7 is equal to the sum of the capacitance C_{WL} between the gate conductor layer 5b to which the word line wiring layer WL is connected and the semiconductor body 7, the capacitance CP_{L} between the gate conductor layer 5a to which the plate line wiring layer PL is connected and the semiconductor body 7, the junction capacitance C_{SL} of the PN junction between the source N⁺ layer 3a to which the source line wiring layer SL is connected and the semiconductor body 7, and the junction capacitance C_{BL} of the PN junction between the drain N⁺ layer 3b to which the bit line wiring layer BL is connected and the semiconductor body 7, and is expressed as follows.

C_{FB}=C_{WL}+C_{PL}+C_{BL}+C_{SL} (1)

Therefore, the coupling ratio 3_{WL} between the word line wiring layer WL and the semiconductor body 7, the coupling ratio β_{PL} between the plate line wiring layer PL and the semiconductor body 7, the coupling ratio β_{BL} between the bit line wiring layer BL and the semiconductor body 7, and the coupling ratio β_{SL} between the source line wiring layer SL and the semiconductor body 7 are expressed as follows.

β_{WL}=C_{WL}/(C_{WL}+C_{PL}+C_{BL}+C_{SL}) (2)

β_{PL}=C_{PL}/(C_{WL}+C_{PL}+C_{BL}+C_{SL}) (3)

β_{BL}=C_{BL}/(C_{WL}+C_{PL}+C_{BL}+C_{SL}) (5)

β_{SL}=C_{SL}/(C_{WL}+C_{PL}+C_{BL}+C_{SL}) (5)

Here, C_{PL}>C_{WL} holds, and therefore, this results in β_{PL}>β_{WL}.

FIG. 2C is a diagram for explaining a change in the voltage V_{FB} of the semiconductor body 7 when the voltage V_{WL} of the word line wiring layer WL rises at the time of a read operation or a write operation and subsequently drops. Here, the potential difference ΔV_{FB} when the voltage V_{FB} of the semiconductor body 7 transitions from a low-voltage state V_{FBL} to a high-voltage state V_{FBH} in response to the voltage V_{WL} of the word line wiring layer WL rising from 0 V to a high-voltage state V_{WLN} is expressed as follows.

ΔV_{FB}=V_{FBH}−V_{FBL}=β_{WL}×V_{WLH} (6)

The coupling ratio β_{WL} between the word line wiring layer WL and the semiconductor body 7 is small and the coupling ratio β_{PL} between the plate line wiring layer PL and the semiconductor body 7 is large, and therefore, ΔV_{FB} is small, and the voltage V_{FB} of the semiconductor body 7 negligibly changes even when the voltage V_{WL} of the word line wiring layer WL changes at the time of a read operation or a write operation.

FIGS. 3AA, 3AB, 3AC and 3B illustrate a write operation (which is an example of “write operation” in the claims) for the dynamic flash memory cell according to the first embodiment of the present invention. FIG. aAA illustrates a mechanism of the write operation, and FIG. 3AB illustrates operation waveforms of the bit line wiring layer BL, the source line wiring layer SL, the plate line wiring layer PL, the word line wiring layer WL, and the semiconductor body 7 that functions as a floating body FB. At time T0, the dynamic flash memory cell is in a “0” erase state, and the voltage of the semiconductor body 7 is equal to V_{FB}“0”. Vss is applied to the bit line wiring layer BL, the source line wiring layer SL, and the word line wiring layer WL, and V_{PLL} is applied to the plate line wiring layer PL. Here, for example, Vss is equal to 0 V and V_{PLL} is equal to 2 V. Subsequently, from time T1 to time T2, when the bit line wiring layer BL rises from Vss to V_{BLH}, in a case where, for example, Vss is equal to 0 V, the voltage of the semiconductor body 7 becomes equal to V_{FB}“0”+β_{BL}×V_{BLN} due to capacitive coupling between the bit line wiring layer BL and the semiconductor body 7.

The description of the write operation for the dynamic flash memory cell will be continued with reference to FIGS. 3AA and 3AB. From time T3 to time T4, the word line wiring layer WL rises from Vss to V_{WLH}. Accordingly, when the threshold voltage for a “0” erase state of a second N-channel MOS transistor region in which the second gate conductor layer 5b to which the word line wiring layer WL is connected surrounds the semiconductor body 7 is denoted by Vt_{WL}“0”, as the voltage of the word line wiring layer WL rises, in a range from Vss to Vt_{WL}“0”, the voltage of the semiconductor body 7 becomes equal to V_{FB}“0”+β_{BL}×V_{BLH}+β_{WL}×Vt_{WL}“0” due to second capacitive coupling between the word line wiring layer WL and the semiconductor body 7. When the voltage of the word line wiring layer WL rises to Vt_{WL}“0” or above, an inversion layer 12b in a ring form is formed in the semiconductor body 7 on the inner periphery of the second gate conductor layer 5b and interrupts the second capacitive coupling between the word line wiring layer WL and the semiconductor body 7.

The description of the write operation for the dynamic flash memory cell will be continued with reference to FIGS. 3AA and 3AB. From time T3 to time T4, for example, a fixed voltage V_{PLL}=2 V is applied to the first gate conductor layer 5a to which the plate line wiring layer PL is connected, and the second gate conductor layer 5b to which the word line wiring layer WL is connected is raised to, for example, V_{WLH}=4 V. As a result, as illustrated in FIG. 3AA, an inversion layer 12a in a ring form is formed in the semiconductor body 7 on the inner periphery of the first gate conductor layer 5a to which the plate line wiring layer PL is connected, and a pinch-off point 13 is present in the inversion layer 12a. As a result, a first N-channel MOS transistor region having the first gate conductor layer 5a operates in the saturation region. In contrast, the second N-channel MOS transistor region having the second gate conductor layer 5b to which the word line wiring layer WL is connected operates in the linear region. As a result, a pinch-off point is not present in the semiconductor body 7 on the inner periphery of the second gate conductor layer 5b to which the word line wiring layer WL is connected, and the inversion layer 12b is formed on the entire inner periphery of the gate conductor layer 5b. The inversion layer 12b that is formed on the entire inner periphery of the second gate conductor layer 5b to which the word line wiring layer WL is connected substantially functions as the drain of the second N-channel MOS transistor region having the second gate conductor layer 5b. As a result, the electric field becomes maximum in a first boundary region of the semiconductor body 7 between the first N-channel MOS transistor region having the first gate conductor layer 5a and the second N-channel MOS transistor region having the second gate conductor layer 5b that are connected in series, and an impact ionization phenomenon occurs in this region. This region is a source-side region when viewed from the second N-channel MOS transistor region having the second gate conductor layer 5b to which the word line wiring layer WL is connected, and therefore, this phenomenon is called a source-side impact ionization phenomenon. By this source-side impact ionization phenomenon, electrons flow from the N⁺ layer 3a to which the source line wiring layer SL is connected toward the N⁺ layer 3b to which the bit line wiring layer BL is connected. The accelerated electrons collide with lattice Si atoms, and electron-positive hole pairs are generated by the kinetic energy. Although some of the generated electrons flow into the first gate conductor layer 5a and into the second gate conductor layer 5b, most of the generated electrons flow into the N⁺ layer 3b to which the bit line wiring layer BL is connected (not illustrated).

As illustrated in FIG. 3AC, a generated group of positive holes 9 (which is an example of “group of positive holes” in the claims) are majority carriers in the semiconductor body 7, with which the semiconductor body 7 is charged to a positive bias. The N⁺ layer 3a to which the source line wiring layer SL is connected is at 0 V, and therefore, the semiconductor body 7 is charged up to the built-in voltage Vb (about 0.7 V) of the PN junction between the N⁺ layer 3a to which the source line wiring layer SL is connected and the semiconductor body 7. When the semiconductor body 7 is charged to a positive bias, the threshold voltages of the first N-channel MOS transistor region and the second N-channel MOS transistor region decrease due to a substrate bias effect.

The description of the write operation for the dynamic flash memory cell will be continued with reference to FIG. 3AB. From time T6 to time T7, the voltage of the word line wiring layer WL drops from V_{WLH} to Vss. During this period, although the second capacitive coupling is formed between the word line wiring layer WL and the semiconductor body 7, the inversion layer 12b interrupts the second capacitive coupling until the voltage of the word line wiring layer WL drops from V_{WLH} to a threshold voltage Vt_{WL}“1” of the second N-channel MOS transistor region or below when the voltage of the semiconductor body 7 is equal to Vb. Therefore, the capacitive coupling between the word line wiring layer WL and the semiconductor body 7 is substantially formed only during a period from when the word line wiring layer WL drops to Vt_{WL}“1” or below to when the word line wiring layer WL drops to Vss. As a result, the voltage of the semiconductor body 7 becomes equal to Vb−β_{WL}×Vt_{WL}“1”. Here, Vt_{WL}“1” is lower than Vt_{WL}“0” described above, and β_{WL}×Vt_{WL}“1” is small.

The description of the write operation for the dynamic flash memory cell will be continued with reference to FIG. 3AB. From time T8 to time T9, the bit line wiring layer BL drops from V_{BLH} to Vss. The bit line wiring layer BL and the semiconductor body 7 are capacitively coupled with each other, and therefore, the “1” write voltage V_{FB}“1” of the semiconductor body 7 becomes as follows at the end.

V_{FB}1“0”=Vb−β_{WL}Vt_{WL}“1”−β_{BL}V_{BLN} (7)

Here, the coupling ratio ρ_{BL} between the bit line wiring layer BL and the semiconductor body 7 is also small. Accordingly, as illustrated in FIG. 3B, the threshold voltage of the second N-channel MOS transistor region of the second channel Si layer 7b to which the word line wiring layer WL is connected decreases. The write operation in which the voltage V_{FB}“1” in the “1” write state of the semiconductor body 7 is assumed to be a first data retention voltage (which is an example of “first data retention voltage” in the claims) is performed to assign logical storage data “1”.

At the time of the write operation, electron-positive hole pairs may be generated by an impact ionization phenomenon in a second boundary region between the first impurity region 3a and the first channel Si layer 7a or in a third boundary region between the second impurity region 3b and the second channel Si layer 7b instead of the first boundary region, and the semiconductor body 7 may be charged with the generated group of positive holes 9.

Mechanisms of an erase operation (which is an example of “erase operation” in the claims) will be described with reference to FIG. 4A to FIGS. 4DA, 4DB, 4DC and 4DD.

FIG. 4A is a memory block circuit diagram for explaining the erase operation. Although nine memory cells CL₁₁ to CL₃₃ in three rows and three columns are illustrated, the actual memory is larger than this matrix. When memory cells are arranged in a matrix, one of the directions of the arrangement is called a row direction (or in rows) and the direction perpendicular to the one of the directions is called “column direction” (or in columns). To each of the memory cells, the source line wiring layer SL, a corresponding one of the bit line wiring layers BL₁ to BL₃, a corresponding one of the plate line wiring layers PL₁ to PL₃, and a corresponding one of the word line wiring layers WL₁ to WL₃ are connected. For example, it is assumed that the memory cells CL₂₁ to CL₂₃ to which the plate line wiring layer PL₂ and the word line wiring layer WL₂ are connected are selected in this block and the erase operation is performed.

A mechanism of the erase operation will be described with reference to FIGS. 4BA, 4BB, 4BC, 4BD and 4C. Here, the semiconductor body 7 between the N⁺ layers 3a and 3b is electrically isolated from the substrate and functions as a floating body. FIG. 4BA is a timing operation waveform diagram of main nodes in the erase operation. In FIG. 4BA, T0 to T12 indicate times from the start to the end of the erase operation. FIG. 4BB illustrates a state at time T0 before the erase operation, in which the group of positive holes 9 generated by an impact ionization phenomenon in the previous cycle are stored in the semiconductor body 7. From time T1 to time T2, the bit line wiring layers BL₁ to BL₃ and the source line wiring layer SL rise from Vss to V_{BLH} and V_{SLH} respectively and are in a high-voltage state. Here, Vss is, for example, equal to 0 V. In this operation, during the subsequent period, namely, a first period from time T3 to time T4, the plate line wiring layer PL₂ selected in the erase operation rises from a first voltage V_{PLL} to a second voltage V_{PLH} and is in a high-voltage state, the word line wiring layer WL₂ selected in the erase operation rises from a third voltage Vss to a fourth voltage V_{WLH} and is in a high-voltage state, and this prevents the inversion layer 12a on the inner periphery of the first gate conductor layer 5a to which the plate line wiring layer PL₂ is connected and the inversion layer 12b on the inner periphery of the second gate conductor layer 5b to which the word line wiring layer WL₂ is connected from being formed in the semiconductor body 7. Therefore, when the threshold voltage of the second N-channel MOS transistor region on the side of the word line wiring layer WL₂ and the threshold voltage of the first N-channel MOS transistor region on the side of the plate line wiring layer PL₂ are denoted by V_{tWL} and V_{tPL} respectively, it is desirable that the voltages V_{BLH} and V_{SLH} satisfy V_{BLH}>V_{WLH}+V_{twL} and V_{SLH}>V_{PLH}+V_{tPL}. For example, in a case where V_{tWL} and V_{tPL} are equal to 0.5 V, V_{WLH} and V_{PLH} need to be set to 3 V, and V_{BLH} and V_{SLH} need to be set to 3.5 V or higher.

The description of the mechanism of the erase operation illustrated in FIG. 4BA will be continued. As the plate line wiring layer PL₂ and the word line wiring layer WL₂ respectively rise to the second voltage V_{PLH} and the fourth voltage V_{WLH} and are in a high-voltage state during the first period from time T3 to time T4, the voltage of the semiconductor body 7 in a floating state is increased due to first capacitive coupling between the plate line wiring layer PL₂ and the semiconductor body 7 and second capacitive coupling between the word line wiring layer WL₂ and the semiconductor body 7. The voltage of the semiconductor body 7 rises from V_{FB}“1” in the “1” write state to a high voltage. This voltage rise is possible because the voltage of the bit line wiring layers BL₁ to BL₃ and that of the source line wiring layer SL are high voltages of V_{BLH} and V_{SLH} respectively and the PN junction between the source N⁺ layer 3a and the semiconductor body 7 and the PN junction between the drain N⁺ layer 3b and the semiconductor body 7 are in a reverse bias state accordingly.

The description of the mechanism of the erase operation illustrated in FIG. 4BA will be continued. Subsequently, during a second period from time T5 to time T6, the voltage of the bit line wiring layers BL₁ to BL₃ and that of the source line wiring layer SL respectively drop from high voltages of V_{BLH} and V_{SLH} to Vss. As a result, the PN junction between the source N⁺ layer 3a and the semiconductor body 7 and the PN junction between the drain N⁺ layer 3b and the semiconductor body 7 are in a forward bias state as illustrated in FIG. 4BC, and a group of remaining positive holes among the group of positive holes 9 in the semiconductor body 7 are discharged to the source N⁺ layer 3a and to the drain N⁺ layer 3b. As a result, the voltage V_{FB} of the semiconductor body 7 becomes equal to the built-in voltage Vb of the PN junction formed by the source N⁺ layer 3a and the P-layer semiconductor body 7 and the PN junction formed by the drain N⁺ layer 3b and the P-layer semiconductor body 7.

The description of the mechanism of the erase operation illustrated in FIG. 4BA will be continued. Subsequently, from time T7 to time T8, the voltage of the bit line wiring layers BL₁ to BL₃ and that of the source line wiring layer SL rise from Vss to high voltages of V_{BLH} and V_{SLH} respectively. With this operation, as illustrated in FIG. 4BD, when the plate line wiring layer PL₂ drops from the second voltage V_{PLH} to the first voltage V_{PLL} and the word line wiring layer WL₂ drops from the fourth voltage V_{WLH} to the third voltage Vss during a third period from time T9 to time T10, the voltage V_{FB} of the semiconductor body 7 efficiently changes from Vb to V_{FB}“0” due to the first capacitive coupling between the plate line wiring layer PL₂ and the semiconductor body 7 and the second capacitive coupling between the word line wiring layer WL₂ and the semiconductor body 7 without the inversion layer 12a on the side of the plate line wiring layer PL₂ or the inversion layer 12b on the side of the word line wiring layer WL₂ being formed in the semiconductor body 7. The voltage difference ΔV_{FB} of the semiconductor body 7 between the “1” write state and the “0” erase state is expressed by the following expressions.

$${V}_{FB} “ 1 ” = Vb - {β}_{WL} \times {Vt}_{WL} “ 1 ” - {β}_{B L} \times {V}_{BLH} \qquad ( 7 )$$

$${V}_{FB} “ 0 ” = Vb - {β}_{WL} \times {V}_{W L H} - {β}_{PL} \times ( {V}_{PLH} - {V}_{PLL} ) \qquad ( 8 )$$

$$Δ {V}_{F B} = {V}_{F B} “ 1 ” - {V}_{FB} “ 0 ” = {β}_{WL} \times {V}_{W L H} + {β}_{PL} \times ( {V}_{P L H} - {V}_{P L L} ) - {β}_{WL} \times {Vt}_{W L} “ 1 ” - {β}_{BL} \times {V}_{B L H} \qquad ( 9 )$$

Here, the sum of β_{WL} and β_{PL} is greater than or equal to 0.8, ΔV_{FB} is large, and a sufficient margin is provided.

As a result, as illustrated in FIG. 4C, a large margin is provided between the “1” write state and the “0” erase state. Here, in the “0” erase state, the threshold voltage on the side of the plate line wiring layer PL₂ is high due to a substrate bias effect. Therefore, when the voltage applied to the plate line wiring layer PL₂ is set to, for example, the threshold voltage or lower, the first N-channel MOS transistor region on the side of the plate line wiring layer PL₂ becomes non-conducting and does not allow the memory cell current to flow therethrough. This state is illustrated in the right part of FIG. 4C.

The description of the mechanism of the erase operation illustrated in FIG. 4BA will be continued. Subsequently, from time T11 to time T12, the voltage of the bit line wiring layers BL₁ to BL₃ drops from V_{BLH} to Vss and that of the source line wiring layer SL drops from V_{SLH} to Vss, and the erase operation ends. At this time, although the bit line wiring layers BL₁ to BL₃ and the source line wiring layer SL slightly decrease the voltage of the semiconductor body 7 due to capacitive coupling, this decrease is equal to the increase in the voltage of the semiconductor body 7 by the bit line wiring layers BL₁ to BL₃ and the source line wiring layer SL from time T7 to time T8 due to capacitive coupling, and therefore, the decrease and the increase in the voltage by the bit line wiring layers BL₁ to BL₃ and the source line wiring layer SL are canceled out, and the voltage of the semiconductor body 7 is not affected consequently. The erase operation in which the voltage V_{FB}“0” in the “0” erase state of the semiconductor body 7 is assumed to be a second data retention voltage (which is an example of “second data retention voltage” in the claims) is performed to assign logical storage data “0”.

Now, a mechanism of the erase operation will be described with reference to FIGS. 4DA, 4DB, 4DC and 4DD. FIGS. 4DA, 4DB, 4DC and 4DD are different from FIGS. 4BA, 4BB, 4BC and 4BD in that the source line wiring layer SL is kept at Vss or put in a floating state and the plate line wiring layer PL₂ is kept at Vss during the erase operation. Accordingly, from time T1 to time T2, even when the bit line wiring layers BL₁ to BL₃ rise from Vss to V_{BLH}, the first N-channel MOS transistor region of the plate line wiring layer PL₂ is non-conducting, and the memory cell current does not flow therethrough. Therefore, the group of positive holes 9 caused by an impact ionization phenomenon are not generated. The others are the same as in FIGS. 4BA, 4BB, 4BC and 4BD, and the bit line wiring layers B₁ to B₃ change between Vss and V_{BLH} and the word line wiring layer WL₂ changes between Vss and V_{WLH}. As a result, as illustrated in FIG. 4DC, the group of positive holes 9 are discharged to the second impurity region, namely, the N⁺ layer 3b, of the bit line wiring layers BL₁ to BL₃.

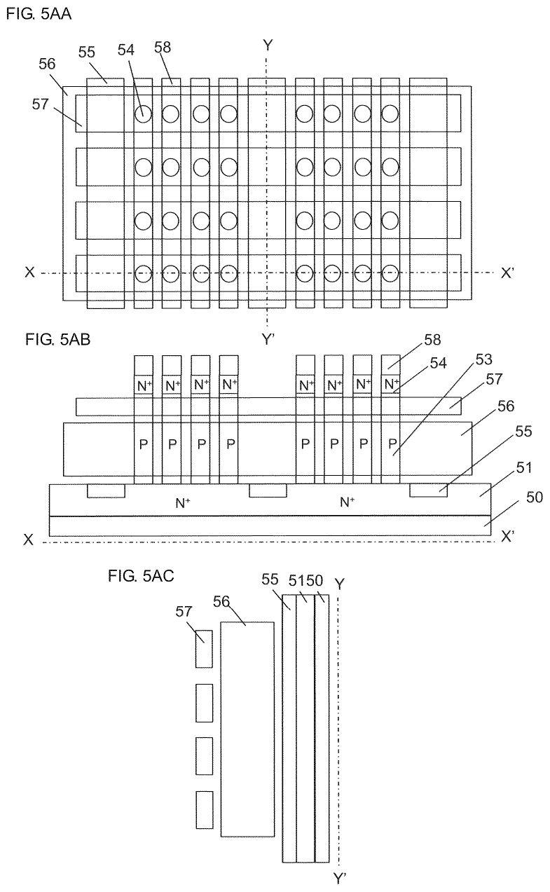

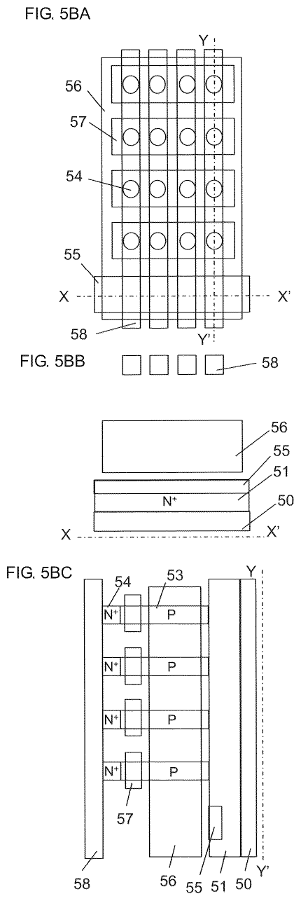

FIGS. 5AA, 5AB, 5AC, 5BA, 5BB and 5BC are diagrams for explaining disposition structures of the source line wiring layer, the word line wiring layer, and the bit line wiring layer of the SGT-including memory device according to the first embodiment of the present invention.

FIGS. 5AA, 5AB and 5AC illustrate an example where a source line wiring layer SL 55 is disposed parallel to a bit line wiring layer BL 58. FIG. 5AA is a plan view of a part of a memory cell block, FIG. 5AB is a cross-sectional view taken along line X-X′ in FIG. 5AA, and FIG. 5AC is a cross-sectional view taken along line Y-Y′ in FIG. 5AA. FIGS. 5AB and 5AC illustrate a semiconductor substrate 50, which is a P layer, and a first impurity region 51, which is an N⁺ layer. In the vertical direction relative to the semiconductor substrate 50, a P layer 53, which is a semiconductor body, and a second impurity region 54 are formed. The source line wiring layer SL 55 is connected to the first impurity region 51, which is an N⁺ layer, in a lower layer and is disposed parallel to the bit line wiring layer BL 58 that is connected to the second impurity region 54, which is an N⁺ layer. In upper layers above the source line wiring layer SL 55, a plate line wiring layer PL 56 and a word line wiring layer WL 57 are disposed perpendicular to the source line wiring layer SL 55. In a further upper layer, the bit line wiring layer BL 58 is disposed parallel to the source line wiring layer SL 55.

As illustrated in FIGS. 5AA and 5AB, one source line wiring layer SL 55 is disposed for each of the pluralities of bit line wiring layers BL 58. In the example illustrated in FIGS. 5AA and 5AB, one source line wiring layer SL 55 is disposed every four bit line wiring layers BL 58. In this case, one source line wiring layer SL 55 can be disposed, for example, every eight, 16, or 32 bit line wiring layers BL 58 in addition to every four bit line wiring layers BL 58, that is, in binary multiples.

Note that the semiconductor substrate 50 may be an SOI substrate or may be a substrate formed of a P-layer substrate in which a well layer is provided.

Figs. SBA, 5BB and 5BC illustrate an example where the source line wiring layer SL 55 is disposed perpendicular to the bit line wiring layer BL 58. FIG. 5BA is a plan view of a part of a memory cell block, FIG. 5BB is a cross-sectional view taken along line X-X′ in FIG. 5BA, and FIG. 5BC is a cross-sectional view taken along line Y-Y′ in FIG. 5BA. FIGS. 5BB and 5BC illustrate the semiconductor substrate 50, which is a P layer, and the first impurity region 51, which is an N⁺ layer. In the vertical direction relative to the semiconductor substrate 50, the P layer 53, which is a semiconductor body, and the second impurity region 54 are formed. The source line wiring layer SL 55 is connected to the first impurity region 51, which is an N⁺ layer, in a lower layer and is disposed perpendicular to the bit line wiring layer BL 58 that is connected to the second impurity region 54, which is an N⁺ layer. In upper layers above the source line wiring layer SL 55, the plate line wiring layer PL 56 and the word line wiring layer WL 57 are disposed parallel to the source line wiring layer SL 55. In a further upper layer, the bit line wiring layer BL 58 is disposed perpendicular to the source line wiring layer SL 55.

As illustrated in FIGS. 5BA and 5BC, one source line wiring layer SL 55 is disposed for each of the pluralities of word line wiring layers WL 57. In the example illustrated in FIGS. 5BA and 5BC, one source line wiring layer SL 55 is disposed every four word line wiring layers WL 57. In this case, one source line wiring layer SL 55 can be disposed, for example, every eight, 16, or 32 word line wiring layers WL 57 in addition to every four word line wiring layers WL 57, that is, in binary multiples.

Note that the source line wiring layer SL 55 illustrated in FIGS. 5AA, 5AB, 5AC, 5BA, 5BB and 5BC may be formed of a buried N⁺ (BN⁺) layer of high concentration provided in the first impurity region 51, which is an N⁺ layer.

Further, the source line wiring layer SL 55 illustrated in FIGS. 5AA, 5AB, 5AC, 5BA, 5BB and 5BC may be formed by making a groove in the first impurity region 51, which is an N⁺ layer, and filling the groove with metal, such as tungsten W or copper Cu, with a damascene process.

FIGS. 6A, 6B and 6C are diagrams for explaining a read operation for the dynamic flash memory cell according to the first embodiment of the present invention. As illustrated in FIG. 6A, when the semiconductor body 7 is charged up to the built-in voltage Vb (about 0.7 V), the threshold voltage of the second N-channel MOS transistor region having the second gate conductor layer 5b to which the word line wiring layer WL is connected decreases due to a substrate bias effect. This state is assigned to logical storage data “1”. As illustrated in FIG. 6B, a memory block selected before writing is in an erase state “0” in advance, and the voltage V_{FB} of the semiconductor body 7 is equal to V_{FB}“0”. With the write operation, a write state “1” is stored at random. As a result, logical storage data of logical “0” and that of logical “1” are created for the word line wiring layer WL. As illustrated in FIG. 6C, the level difference between the two threshold voltages of the word line wiring layer WL is used to perform reading by a sense amplifier. When the voltage applied to the first gate conductor layer 5a connected to the plate line wiring layer PL is set to a voltage higher than the threshold voltage at the time of logical storage data “1” and lower than the threshold voltage at the time of logical storage data “0” in reading of logical “0” data, a property that a current does not flow even when the voltage of the word line wiring layer WL is increased can be attained.

Regardless of whether the horizontal cross-sectional shape of the Si column 2 illustrated in FIG. 1 is a round shape, an elliptic shape, or a rectangular shape, the operations of the dynamic flash memory described in this embodiment can be performed. Further, a dynamic flash memory cell having a round shape, a dynamic flash memory cell having an elliptic shape, and a dynamic flash memory cell having a rectangular shape may coexist on the same chip.

With reference to FIG. 1, the dynamic flash memory element including, for example, an SGT in which the first gate insulator layer 4a and the second gate insulator layer 4b that surround the entire side surface of the Si column 2 standing on the substrate 1 in the vertical direction are provided and which includes the first gate conductor layer 5a and the second gate conductor layer 5b that entirely surround the first gate insulator layer 4a and the second gate insulator layer 4b has been described. As described in this embodiment, the dynamic flash memory element needs to have a structure that satisfies the condition that the group of positive holes 9 generated by an impact ionization phenomenon are retained in the semiconductor body 7. For this, the semiconductor body 7 needs to have a floating body structure isolated from the substrate 1. Alternatively, the dynamic flash memory element may have a device structure using SOI (Silicon On Insulator) (see, for example, J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), E. Yoshida and T. Tanaka: “A design of a capacitorless 1T-DRAM cell using gate-induced drain leakage (GIDL) current for low-power and high-speed embedded memory”, IEEE IEDM, pp. 913-916, December 2003, and E. Yoshida and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-69, April 2006). In this device structure, the bottom portion of the semiconductor body is in contact with an insulating layer of the SOI substrate, and the other portion of the semiconductor body is surrounded by a gate insulator layer and an element isolation insulating layer. With such a structure, the semiconductor body also has a floating body structure. Accordingly, the dynamic flash memory element provided in this embodiment needs to satisfy the condition that the semiconductor body has a floating body structure.

To write “1”, electron-positive hole pairs may be generated by using a gate-induced drain leakage (GIDL) current, and the semiconductor body 7 may be filled with the generated group of positive holes.

Expressions (1) to (12) provided in the specification and in the drawings are expressions used to qualitatively explain the phenomena, and are not intended to limit the phenomena.

Although the reset voltages of the word line wiring layer WL, the bit line wiring layer BL, and the source line wiring layer SL are specified as Vss in the descriptions of FIGS. 3AA, 3AB, 3AC and 3B, the reset voltages of the respective wiring layers may be set to different voltages.

Although FIG. 4A to FIGS. 4DA, 4DB, 4DC and 4DD illustrate example conditions of the erase operation, the voltages applied to the source line wiring layer SL, the plate line wiring layer PL, the bit line wiring layer BL, and the word line wiring layer WL may be changed as long as a state in which the group of positive holes 9 in the semiconductor body 7 are discharged through one or both of the N⁺ layer 3a and the N⁺ layer 3b can be attained. Further, in the erase operation, a voltage may be applied to the source line wiring layer SL of a selected page, and the bit line wiring layer BL may be put in a floating state. In the erase operation, a voltage may be applied to the bit line wiring layer BL of a selected page, and the source line wiring layer SL may be put in a floating state.

In FIG. 1, in the vertical direction, in a part of the semiconductor body 7 surrounded by the insulating layer 6, which is a first insulating layer, the potential distribution of the first channel Si layer 7a and that of the second channel Si layer 7b are connected and formed. Accordingly, the first channel Si layer 7a and the second channel Si layer 7b that constitute the semiconductor body 7 are connected in the vertical direction in the region surrounded by the insulating layer 6 that is the first insulating layer.

Note that in FIG. 1, it is desirable to make the length of the first gate conductor layer 5a, in the vertical direction, to which the plate line wiring layer PL is connected further longer than the length of the second gate conductor layer 5b, in the vertical direction, to which the word line wiring layer WL is connected to attain C_{CP}>C_{WL}. However, when the plate line wiring layer PL is only added, the capacitive coupling ratio (C_{WL}/(C_{PL}+C_{BL}+C_{BL}+C_{BL})) of the word line wiring layer WL to the semiconductor body 7 decreases. As a result, the potential change ΔV_{FB} of the semiconductor body 7 that is a floating body decreases.

As the voltage V_{PLL} of the plate line wiring layer PL, for example, a different fixed voltage may be applied in operation modes other than a mode in which selective erasing is performed in a block erase operation.

In FIG. 1, the first gate conductor layer 5a may be divided into two or more gate conductor layers in plan view or in the vertical direction, and the gate conductor layers may each function as a conductive electrode of the plate line wiring layer and may be operated synchronously or asynchronously at identical driving voltages or different driving voltages. Similarly, the second gate conductor layer 5b may be divided into two or more gate conductor layers in plan view or in the vertical direction, and the gate conductor layers may each function as a conductive electrode of the word line wiring layer and may be operated synchronously or asynchronously at identical driving voltages or different driving voltages. In this case, the operations of the dynamic flash memory can also be performed. In a case where the first gate conductor layer 5a is divided into two or more gate conductor layers, at least one of the first gate conductor layers obtained as a result of division assumes the roles of the first gate conductor layer 5a described above. In a case where the second gate conductor layer 5b is divided into two or more gate conductor layers, at least one of the second gate conductor layers obtained as a result of division assumes the roles of the second gate conductor layer 5b described above. In the vertical direction, isolated gate conductor layers obtained from one of the first gate conductor layer 5a or the second gate conductor layer 5b may be disposed on the respective sides of the other of the first gate conductor layer 5a or the second gate conductor layer 5b.

The above-described conditions of voltages applied to the bit line wiring layer BL, the source line wiring layer SL, the word line wiring layer WL, and the plate line wiring layer PL and the voltage of the floating body are examples for performing basic operations including the erase operation, the write operation, and the read operation, and other voltage conditions may be employed as long as the basic operations of the present invention can be performed.

In FIG. 1, the first gate conductor layer 5a may be connected to the word line wiring layer WL and the second gate conductor layer 5b may be connected to the plate line wiring layer PL. In this case, the above-described operations of the dynamic flash memory can also be performed.

Further, a junction-less structure in which the conductivities of the N⁺ layers 3a and 3b and the P-layer semiconductor body 7 of the dynamic flash memory cell illustrated in FIG. 1 are made identical may be employed. The same applies to other embodiments.

This embodiment has the following features.

### Feature 1

The dynamic flash memory cell of this embodiment is constituted by the N⁺ layers 3a and 3b that function as the source and the drain, the semiconductor body 7, the first gate insulator layer 4a, the second gate insulator layer 4b, the first gate conductor layer 5a, and the second gate conductor layer 5b, which are formed in a columnar form as a whole. The N⁺ layer 3a that functions as the source is connected to the source line wiring layer SL, the N⁺ layer 3b that functions as the drain is connected to the bit line wiring layer BL, the first gate conductor layer 5a is connected to the plate line wiring layer PL, and the second 3b gate conductor layer 5b is connected to the word line wiring layer WL. A structure is employed in which the gate capacitance of the first gate conductor layer 5a to which the plate line wiring layer PL is connected is larger than the gate capacitance of the second gate conductor layer 5b to which the word line wiring layer WL is connected, which is a feature. In the dynamic flash memory cell, the first gate conductor layer and the second gate conductor layer are stacked in the vertical direction. Accordingly, even when the structure is employed in which the gate capacitance of the first gate conductor layer 5a to which the plate line wiring layer PL is connected is larger than the gate capacitance of the second gate conductor layer 5b to which the word line wiring layer WL is connected, the memory cell area does not increase in plan view. Accordingly, a high-performance and highly integrated dynamic flash memory cell can be implemented.

### Feature 2

With the disposition structures of the source line wiring layer, the word line wiring layer, and the bit line wiring layer of the dynamic flash memory cell according to this embodiment, the resistance of the source line wiring layer can be substantially decreased. As a result, the voltage of the source line wiring layer supplied to the dynamic flash memory cell becomes stable, and the erase operation, the write operation, and the read operation, which are basic operations of the memory cell, can be performed with high reliability. Further, a decrease in the resistance of the source line wiring layer allows the erase operation, the write operation, and the read operation to be performed at high speed.

### Feature 3

In terms of the roles of the first gate conductor layer 5a to which the plate line wiring layer PL is connected in the dynamic flash memory cell according to this embodiment, in the write operation and in the read operation performed by the dynamic flash memory cell, the voltage of the word line wiring layer WL changes. At this time, the plate line wiring layer PL assumes the role of decreasing the capacitive coupling ratio between the word line wiring layer WL and the semiconductor body 7. As a result, an effect on changes in the voltage of the semiconductor body 7 when the voltage of the word line wiring layer WL changes can be substantially suppressed. Accordingly, the difference between the threshold voltages of the SGT transistor of the word line wiring layer WL indicating logical “0” and logical “1” can be increased. This leads to an increased operation margin of the dynamic flash memory cell. When the voltage applied to the first gate conductor layer 5a connected to the plate line wiring layer PL is set to a voltage higher than the threshold voltage at the time of logical storage data “1” and lower than the threshold voltage at the time of logical storage data “0” in data reading, a property that a current does not flow even when the voltage of the word line wiring layer WL is increased can be attained. This leads to a further increased operation margin of the dynamic flash memory cell.

### Feature 4

For the dynamic flash memory cells in this embodiment, although the erase operation described with reference to FIG. 4A to FIGS. 4DA, 4DB, 4DC and 4DD is performed, rewriting is performed with a low electric field far lower than that in a flash memory. Therefore, in terms of reliability, the limit of the number of rewrites in the erase operation need not be specified.

### Other Embodiments

Although the Si column is formed in the present invention, a semiconductor column made of a semiconductor material other than Si may be formed. The same applies to other embodiments according to the present invention.

In a vertical NAND-type flash memory circuit, memory cells that are stacked in a plurality of tiers in the vertical direction and each of which is constituted by a semiconductor column, which functions as the channel, and a tunnel oxide layer, a charge storage layer, an interlayer insulating layer, and a control conductor layer that surround the semiconductor column are formed. At the semiconductor columns on both ends of these memory cells, a source line impurity region corresponding to the source and a bit line impurity region corresponding to the drain are disposed respectively. In addition, for one memory cell, when one of the memory cells on both sides of the one memory cell functions as the source, the other functions as the drain. Accordingly, the vertical NAND-type flash memory circuit is one type of SGT circuit. Therefore, the present invention is also applicable to a circuit in which a NAND-type flash memory circuit coexists.

To write “1”, electron-positive hole pairs may be generated by a gate-induced drain leakage (GIDL) current described in E. Yoshida and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-69, April 2006, and the floating body FB may be filled with the generated group of positive holes. The same applies to other embodiments according to the present invention.

Even with a structure in which the polarity of the conductivity type of each of the N⁺ layers 3a and 3b and the P-layer Si column 2 in FIG. 1 is reversed, the operations of the dynamic flash memory can be performed. In this case, in the Si column 2 that is of N-type, the majority carriers are electrons. Therefore, a group of electrons generated by impact ionization are stored in the semiconductor body 7, and a “1” state is set.

Various embodiments and modifications can be made to the present invention without departing from the spirit and scope of the present invention in a broad sense. The above-described embodiments are intended to explain examples of the present invention and are not intended to limit the scope of the present invention. Any of the above-described embodiments and modifications can be combined. Further, the above-described embodiments from which some of the configuration requirements are removed as needed are also within the scope of the technical spirit of the present invention.

With the semiconductor-element-including memory device according to the present invention, a high-density and high-performance dynamic flash memory that is an SGT-including memory device can be obtained.

What is claimed is:

1. A semiconductor element memory device comprising a plurality of memory cells disposed in a matrix, each of the memory cells comprising:
a semiconductor body that stands on a substrate in a vertical direction relative to the substrate;
a first impurity region and a second impurity region that are respectively disposed at a lower end and an upper end of the semiconductor body in the vertical direction relative to the substrate;
a gate insulator layer that is in contact with a side surface of the semiconductor body between the first impurity region and the second impurity region;
a first gate conductor layer that partially or entirely covers the gate insulator layer; and
a second gate conductor layer that is adjacent to the first gate conductor layer and that is in contact with a side surface of the gate insulator layer, wherein
in each of the memory cells,
voltages applied to the first gate conductor layer, the second gate conductor layer, the first impurity region, and the second impurity region are controlled to retain a group of positive holes, generated by an impact ionization phenomenon or a gate-induced drain leakage current, inside the semiconductor body,
in a write operation, a voltage of the semiconductor body is made equal to a first data retention voltage that is higher than the voltage of one of the first impurity region or the second impurity region or the voltages of both of the first impurity region and the second impurity region,
in an erase operation, the voltages applied to the first impurity region, the second impurity region, the first gate conductor layer, and the second gate conductor layer are controlled to discharge the group of positive holes through one or both of the first impurity region and the second impurity region, and the voltage of the semiconductor body is made equal to a second data retention voltage lower than the first data retention voltage,
the first impurity region of the memory cell is connected to a source line wiring layer, the second impurity region thereof is connected to a bit line wiring layer, one of the first gate conductor layer or the second gate conductor layer thereof is connected to a word line wiring layer, and the other of the first gate conductor layer or the second gate conductor layer is connected to a first driving control line wiring layer, and
in the vertical direction relative to the substrate, the source line wiring layer is connected to the first impurity region at a position lower than the first driving control line wiring layer and the word line wiring layer.

2. The semiconductor element memory device according to claim 1, wherein
in the vertical direction relative to the substrate, the source line wiring layer is disposed in a layer lower than the first driving control line wiring layer and the word line wiring layer.

3. The semiconductor element memory device according to claim 1, wherein
the source line wiring layer is disposed parallel to the bit line wiring layer.

4. The semiconductor element memory device according to claim 1, wherein
the source line wiring layer is disposed perpendicular to the word line wiring layer.

5. The semiconductor element memory device according to claim 1, wherein
the source line wiring layer is disposed perpendicular to the bit line wiring layer.

6. The semiconductor element memory device according to claim 1, wherein
the source line wiring layer is disposed parallel to the word line wiring layer.

7. The semiconductor element memory device according to claim 3, wherein
one source line wiring layer is disposed for each of pluralities of bit line wiring layers each of which is the bit line wiring layer.

8. The semiconductor element memory device according to claim 6, wherein
one source line wiring layer is disposed for each of pluralities of word line wiring layers each of which is the word line wiring layer.

9. The semiconductor element memory device according to claim 7, wherein
one source line wiring layer is disposed for each of the pluralities of bit line wiring layers in binary multiples.

10. The semiconductor element memory device according to claim 8, wherein
one source line wiring layer is disposed for each of the pluralities of word line wiring layers in binary multiples.

11. The semiconductor element memory device according to claim 1, wherein
a first gate capacitance between the first gate conductor layer and the semiconductor body is larger than a second gate capacitance between the second gate conductor layer and the semiconductor body.

12. The semiconductor element memory device according to claim 1, wherein
one or both of the first gate conductor layer and the second gate conductor layer is divided into two or more isolated gate conductor layers in plan view or in the vertical direction, and the isolated gate conductor layers are operated synchronously or asynchronously.

13. The semiconductor element memory device according to claim 12, wherein
in the vertical direction, the isolated gate conductor layers obtained from one of the first gate conductor layer or the second gate conductor layer are disposed on respective sides of the other of the first gate conductor layer or the second gate conductor layer.
